(19) United States
(12) Patent Application Publication
(10) Pub. No.: US 2024/0003010 A1
(43) Pub. Date: Jan. 4, 2024

(54) BACKSIDE DEPOSITION AND LOCAL STRESS MODULATION FOR WAFER BOW COMPENSATION

(71) Applicant: Lam Research Corporation, Fremont, CA (US)

(72) Inventors: Yanhui Huang, Sherwood, OR (US); Vignesh Chandrasekar, King City, OR (US); Shriram Vasant Bapat, Beaverton, OR (US); Adriana Vintila, Wilsonville, OR (US)

(21) Appl. No.: 18/255,287

(22) PCT Filed: Nov. 19, 2021
(86) PCT No.: PCT/US2021/060159

§ 371 Date: May 31, 2023

Related U.S. Application Data
(60) Provisional application No. 63/199,044, filed on Dec. 3, 2020.

(51) Int. Cl. C23C 16/455; H01L 21/02; H01L 21/66; H01L 23/00; H01J 37/32

(52) U.S. Cl. CPC C23C 16/45597; C23C 16/45565; H01L 21/02274; H01L 22/12; H01L 23/562; H01J 37/32449

(57) ABSTRACT

In A bow compensation layer deposited on a backside of a bowed semiconductor substrate may modulate stress to mitigate asymmetric bowing. In some implementations, the bow compensation layer may be formed by varying precursor concentration adjacent to the backside according to a non-linear mass flow profile along the bowed semiconductor substrate. Precursor flow may be varied in a manner to match or substantially match a parabolic or polynomial function. In some implementations, a showerhead pedestal may vary precursor flow along the bowed semiconductor substrate, where the showerhead pedestal is divided into multiple zones for delivering a first gas to a first zone of a plenum volume and a second gas to a second zone of the plenum volume.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor manufacturing processes involve many deposition and etching operations, which can change wafer bow drastically. For example, in 3D-NAND fabrication, which is gradually replacing 2D-NAND chips due to lower cost and higher reliability in various applications, multi-stacked films with thick, high stress carbon-based hard masks and/or metallization lines can cause significant wafer warpage, leading to frontside lithographic overlay mismatch, or even wafer bow beyond a chucking limit of an electrostatic chuck.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of depositing a bow compensation layer on a semiconductor substrate. The method includes providing a bowed semiconductor substrate having one or more tensile regions and one or more compressive regions, depositing a compressive film having a first non-linear thickness profile on a backside of the bowed semiconductor substrate, and depositing a tensile film having a second non-linear thickness profile on the backside of the bowed semiconductor substrate prior to or after depositing the compressive film. The compressive film and the tensile film together form a bow compensation layer.

In some implementations, the first non-linear thickness profile is a first parabolic-shaped profile and the second non-linear thickness profile is a second parabolic-shaped profile. In some implementations, the first parabolic-shaped profile opens upwards or downwards, and the second parabolic-shaped profile opens in a direction opposite the first parabolic-shaped profile. In some implementations, the bow compensation layer is flat or substantially flat. In some implementations, each of the first and second non-linear thickness profiles matches or substantially matches a polynomial function. In some implementations, the bowed semiconductor substrate is saddle-shaped prior to depositing the bow compensation layer. In some implementations, the bowed semiconductor substrate is asymmetrically bowed having a warpage equal to or greater than +300 μm or equal to or less than −300 μm, and where the bowed semiconductor substrate after deposition of the bow compensation layer is between −300 μm and +300 μm. In some implementations, depositing the compressive film includes controlling a first precursor concentration from a showerhead pedestal to vary across the backside of the bowed semiconductor substrate, where depositing the tensile film comprises controlling a second precursor concentration from the showerhead pedestal to vary across the backside of the bowed semiconductor substrate. In some implementations, the showerhead pedestal includes a first supply tube and a second supply tube in a plenum volume of the showerhead pedestal, where the first supply tube flows a first gas to a first zone of the plenum volume and the second supply tube flows a second gas to a second zone of the plenum volume during deposition of the compressive film or the tensile film.

Also provided herein is a showerhead. The showerhead includes a faceplate that includes a plurality of gas distribution holes through which gas is flowed out of the showerhead, a backplate opposite the faceplate and defining a plenum volume therebetween, a first supply tube in the plenum volume, the first supply tube having a plurality of first holes that supplies a first gas into the plenum volume, a second supply tube in the plenum volume, the second supply tube having a plurality of second holes that supplies a second gas into the plenum volume, and a plurality of baffles in the plenum volume. The plurality of baffles are configured to at least isolate the first gas from the second gas in the plenum volume.

In some implementations, the first supply tube is orthogonal to the second supply tube along a reference plane of the plenum volume. In some implementations, the plurality of baffles include a plurality of first baffles and a plurality of second baffles, where the plurality of first baffles are parallel to the first supply tube and on opposite sides of the first supply tube to isolate the first gas in a first zone from a second zone of the plenum volume, and where the plurality of second baffles include at least two baffles parallel to the first supply tube and on opposite sides of the first supply tube further from the plurality of first baffles, where the plurality of second baffles are configured to divide a flow of the second gas in the second zone into a plurality of sections. In some implementations, the first gas flows out of the faceplate from the first zone of the plenum volume and the second gas flows out of the faceplate from the second zone of the plenum volume, where the faceplate is configured to face a backside of a semiconductor substrate. In some implementations, a diameter of each of the plurality of first holes across the first supply tube is uniform, and where a diameter of the second holes in each of the plurality of sections in the second zone is non-uniform. In some implementations, a height of each of the plurality of baffles spans a gap distance between the backplate and the faceplate. In some implementations, the showerhead further includes a center plug in the plenum volume and in fluid communication with each of the first supply tube and the second supply tube, where the center plug directs a flow of the first gas to the first supply tube and a flow of the second gas to the second supply tube. In some implementations, the first gas is a precursor gas and the second gas is a dilution gas, In some implementations, the showerhead further includes a stem connected to the backplate and in fluid communication with the plenum volume, where the stem includes one or more gas delivery lines that supplies the first gas and the second gas to the first supply tube and the second supply tube.

Also provided herein is a showerhead. The showerhead includes a faceplate that comprises a plurality of gas distribution holes through which gas is flowed out of the showerhead, a backplate opposite the faceplate and defining a plenum volume therebetween, one or more baffles in the plenum volume that divides the plenum volume into at least a first zone and a second zone, and one or more gas inlets coupled to the backplate that delivers a first gas and a second gas into the plenum volume, where the first gas is configured to be delivered to the first zone and the second gas is configured to be delivered to the second zone.

In some implementations, the plurality of gas distribution holes comprises first holes in fluid communication with the first zone and second holes in fluid communication with the second zone, wherein a density of the first holes is different than a density of the second holes.

### BRIEF DESCRIPTION OF THE DRAWINGS

FIG. 1 shows a perspective view of a bowed semiconductor substrate illustrating wafer bowing in an x-axis direction and a y-axis direction.

FIG. 2A shows a top view in an x-y plane of a schematic of an example bowed semiconductor substrate.

FIG. 2B shows a side view in a y-axis direction of the bowed semiconductor substrate of FIG. 2A.

FIG. 2C shows a side view in an x-axis direction of the bowed semiconductor substrate of FIG. 2A.

FIG. 3 illustrates a flow diagram of an example method of forming a bow compensation

layer to mitigate asymmetric bowing in a bowed semiconductor substrate according to some implementations.

FIGS. 4A-4C show cross-sectional schematic illustrations of various stages of forming a bow compensation layer to mitigate asymmetric bowing in a bowed semiconductor substrate according to some implementations.

FIG. 5 shows a graph illustrating a thickness profile and a stress profile for each of (i) a compressive film, (ii) a tensile film, and (iii) a bow compensation layer that combines the compressive film and the tensile film according to some implementations.

FIG. 6 shows a graph illustrating a desired profile and a simulated profile of gas reactant flowing from a showerhead pedestal to a backside of a bowed semiconductor substrate according to some implementations.

FIG. 7A shows a top view of a schematic of an example showerhead pedestal with various hole patterns in at least two zones according to some implementations.

FIG. 7B shows a side view of a schematic of an example showerhead pedestal with differing hole densities in at least two zones according to some implementations.

FIG. 7C shows a side view of a schematic of an example showerhead pedestal with dead zones in between at least two zones according to some implementations.

FIG. 8A shows a side view of a schematic of an example concave showerhead pedestal to provide varying gap distances to a backside of a bowed semiconductor substrate according to some implementations.

FIG. 8B shows a side view of a schematic of an example convex showerhead pedestal to provide varying gap distances to a backside of a bowed semiconductor substrate according to some implementations.

FIG. 9A shows a side view of a schematic of an example showerhead pedestal having a plenum volume separated into a first zone for delivering reactant gas and a second zone for delivering dilution gas according to some implementations.

FIG. 9B shows a side view of a schematic of an example baffle separating the first zone

from the second zone in the showerhead pedestal of FIG. 9A.

FIG. 10A shows a perspective view of various components of an example multi-zone showerhead pedestal including a first supply tube delivering a first gas to a first zone and a second supply tube delivering a second gas to a second zone according to some implementations.

FIG. 10B shows a perspective view of the first supply tube and the second supply tube

of the multi-zone showerhead pedestal of FIG. 10A.

FIG. 10C shows a top perspective view showing the first supply tube, the second supply tube, and baffles arranged over a backplate of the multi-zone showerhead pedestal of FIG. 10A.

FIG. 10D shows a cross-sectional schematic view of the multi-zone showerhead pedestal of FIG. 10A.

FIG. 11 shows a graph illustrating inert gas flow from a showerhead pedestal in different sections of a zone according to some implementations.

FIG. 12 shows a graph illustrating precursor mass flow profile from a showerhead pedestal for various ratios of precursor gas flow rate to inert gas flow rate according to some implementations.

FIG. 13 illustrates a schematic diagram of an example process tool for performing operations for stress modulation according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials.

Semiconductor fabrication processes involve formation of various structures, many of which may be two-dimensional. As semiconductor device dimensions shrink and devices are scaled to be smaller, the density of features across a semiconductor substrate increases, resulting in layers of material etched and deposited in various ways, including in three dimensions. For example, 3D-NAND is one technology that is becoming increasingly popular due to lower cost and increased memory density compared to other techniques, such as 2D-NAND, and higher reliability in various applications. During the fabrication of a 3D-NAND structure, wafer bow can change drastically. For example, deposition of thick hard mask materials and etching of trenches along a wafer surface in fabricating a 3D-NAND structure can cause wafer bowing. As layers of films are stacked on top of each other during fabrication, more stress is introduced to the semiconductor wafer which can cause bowing. Bowing can be measured using an optical technique. Wafer bowing can be measured or evaluated by obtaining a wafer map or stress map. Bowing can be quantified using a bow value or warpage value as described herein, which is measured as the vertical distance between the lowest point of the semiconductor wafer to the highest point on the wafer. The warpage value can be along one or more axes—for example, an asymmetrically warped wafer may have an x-axis warpage and/or a y-axis warpage.

In a bow-shaped wafer, the lowest point s the center of the wafer and the highest point is the edge of the wafer. In a dome-shaped wafer, the lowest point is the edge of the wafer and the highest point is the center of the wafer. Bow-shaped and dome-shaped wafers have symmetrical or largely symmetrical bowing. Wafers can also have asymmetric bowing. In asymmetric bowing, warpage is measured along an x-axis and a y-axis. An asymmetrically bowed wafer has different values for the x-axis warpage and y-axis warpage. In some cases, an asymmetrically bowed wafer has a negative x-axis warpage and a positive y-axis warpage. In some cases, an asymmetrically bowed wafer has a positive x-axis warpage and a negative y-axis warpage. In some cases, an asymmetrically bowed wafer has both a positive x-axis warpage and a positive y-axis warpage, but the warpage values are different. In some cases, an asymmetrically bowed wafer has both a negative x-axis warpage and a negative y-axis warpage, but the warpage values are different. One example of an asymmetrically bowed wafer is a saddle-shaped wafer. For a saddle-shaped wafer, in one example, the warpage on the x-axis may be +200 μm and the warpage on the y-axis may be −200 μm. Saddle-shaped wafers have two opposing edges of the wafer that are curved upward while another two opposing edges of the wafer are curved downward. As used herein, warpage can refer to any deviation from planarity exhibited by a wafer, where a bow-shaped wafer, dome-shaped wafer, and saddle-shaped wafer are examples of different types of warpage in a wafer.

Bowing can cause problems with subsequent processing, such as during lithography, as etching can be uneven if the semiconductor substrate is warped. High bowing can be caused by deposition of thick, high stress carbon hard mask layer. Additionally, due to multi-stacked films and the presence of thick, high stress carbon-based hard masks used in such fabrication processes, etching can cause some asymmetric warpage and deposition processes can introduce significant wafer warpage of up to a variation between +500 μm to −1300 μm bow. For example, an ashable hard mask may have a stress value of up to −1000 MPa. and have a bow value of up to −1000 μm. In some cases, a high aspect ratio slit etch and metal fill (e.g., tungsten fill) can induce large anisotropic stress on the semiconductor substrate.

Addressing such wafer warpage can be a challenge as subsequent or downstream processing may be affected by a wafer warpage exceeding ±200 μm, exceeding ±300 μm or exceeding ±500 μm. For instance, mechanical wafer handling may be affected due to wafer warpage, where wafers that are not flat may not be gripped or held effectively by a wafer robot or wafer handling mechanism. Additionally, wafer warpage may contribute to process non-uniformity, where downstream etch, deposition, or clean operations may be adversely affected due to processing non-uniformities across a surface of the wafer. In some cases, processing of highly warped wafers may cause further warping. For example, etching of a trench in one direction can cause warping in asymmetric bowing due to asymmetric stress on the wafer. Moreover, lithography operations may be adversely affected by wafer warpage as precise patterns are unable to be formed. When wafers are used in subsequent processing that involve chucking of the wafer to an electrostatic chuck, highly warped wafers may not be processed in some tools. Many electrostatic chucks have a “chucking limit,” which is defined as the maximum warpage tolerated before the wafer cannot be effectively chucked. For example, some electrostatic chucks have a chucking limit of about ±300 μm. Warped wafers that exceed the chucking limit may not be processed in such instances.

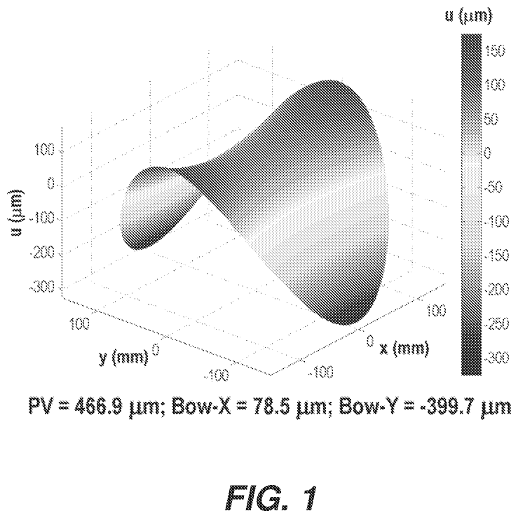

FIG. 1 shows a perspective view of a bowed semiconductor substrate illustrating wafer bowing in an x-axis direction and a y-axis direction. The bowed semiconductor substrate is superimposed in a three-dimensional (3-D) coordinate system, with a reference plane of the bowed semiconductor substrate defined by the x-axis direction and y-axis direction, and with the u-axis indicative of warpage. As shown in FIG. 1, the bowed semiconductor substrate is asymmetrically bowed, meaning that the values for x-axis warpage and y-axis warpage are different. Warpage in the x-axis is +78.5 μm and warpage in the y-axis is μ399.7 μm. This creates bowing that is saddle-shaped. As discussed above, warpage refers to any deviation from planarity exhibited by a semiconductor substrate, where a saddle-shaped wafer represents an example of warpage in a semiconductor substrate.

As 3D-NAND technologies continue to scale up and high-aspect ratio features become increasingly more common, new challenges are emerging related to localized stress and inter-die stress variations on semiconductor substrates. Localized stress and inter-die stress variations may lead to block-bending, cell cross-talk, cell loss, and/or cell misalignments. Localized stress refers to stress changes that occur within a wafer in a non-uniform manner. Poorly compensated/corrected localized stress may lead to localized wafer topology changes, which in turn may lead to poor alignment during lithography. Such poor alignment is typically viewed in terms of in-plane distortion (IPD), which is a quantification of the vector displacement of on-wafer alignment marks from their expected positions due to wafer topology. High IPD during lithography may lead to undesirable changes in critical dimensions or any other feature that is defined in a lithographic step, and so the foregoing phenomena of block-blending, cell cross-talk, cell loss, and/or cell misalignments can arise due to lithographic errors.

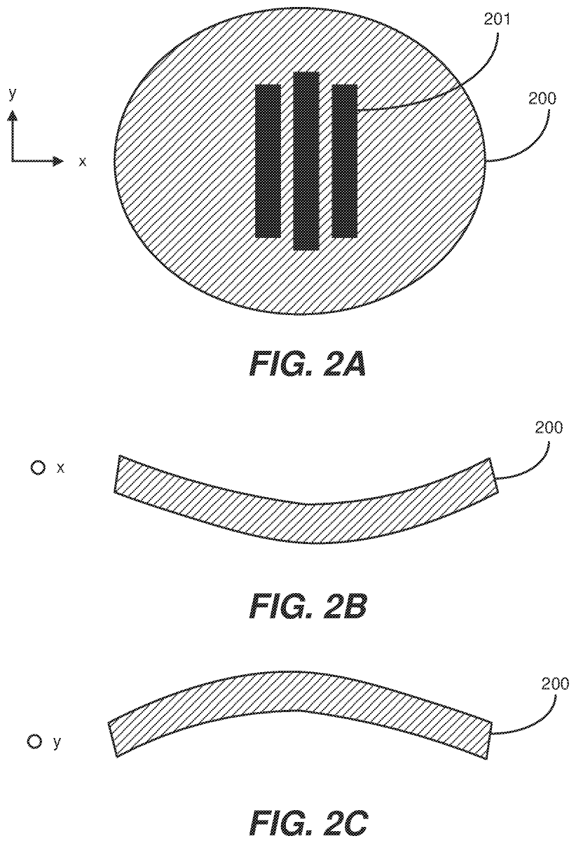

FIGS. 2A-2C illustrate an example of localized stress variations that may lead to asymmetric bowing. FIG. 2A shows a top view in an x-y plane of a schematic of an example bowed semiconductor substrate. A semiconductor substrate 200 may include metal lines 201 deposited on the semiconductor substrate 200. FIG. 2B shows a side view in a y-axis direction of the bowed semiconductor substrate of FIG. 2A. As shown in FIG. 2B, the semiconductor substrate 200 is curved downward towards a center of the bowed semiconductor substrate from a perspective of the y-axis. FIG. 2C shows a side view in an x-axis direction of the bowed semiconductor substrate of FIG. 2A. As shown in FIG. 2C, the semiconductor substrate 200 is curved upward towards the center of the bowed semiconductor substrate from a perspective of the x-axis.

Some techniques exist for addressing bowing of semiconductor substrates. In some cases, techniques can be used to deposit a bow compensation layer on a backside of the semiconductor substrate. In some instances, application of backside deposition with a bow compensation layer has largely been limited to monotonic global wafer warpage mitigation. Specifically, techniques for addressing bowing of semiconductor substrates may be limited to techniques that are axially symmetric or multi-axially symmetric. Alternatively, in some instances, application of backside deposition with a bow compensation layer may address asymmetric bowing using masks or precursor zoning techniques. Localized stress modulation may be achieved by delivering precursor material to certain areas or regions of bowed semiconductor substrate using a carrier ring mask. Localized stress modulation may be achieved using precursor zoning employing multiple plenums to control the delivery of gas to different locations. However, such techniques have been limited or ineffective due to high TPD overlay and problems associated with chucking the semiconductor substrate. Issues of high overlay error and vacuum chucking may be a result of sharp transitions of film stress between zones and the difficulty in designing a zone layout that minimizes local topography variation.

The present disclosure provides a method for mitigating asymmetric bowing in a bowed semiconductor substrate by backside deposition. Precursor control from a showerhead pedestal may provide a desired thickness profile in one or more films deposited on a backside of the bowed semiconductor substrate. The one or more deposited films make up a bow compensation layer. A stress profile of the bow compensation layer may be described by a polynomial function. As a result, the bow compensation layer may compensate or correct localized stress in an asymmetrically bowed semiconductor substrate. In some implementations, the bow compensation layer may be formed by a film stacking approach by depositing multiple films of different thickness profiles. In some implementations, a compressive film having a non-linear thickness profile is deposited on a backside of the bowed semiconductor substrate. A tensile film having a different non-linear thickness profile is deposited on the backside of the bowed semiconductor substrate. The order of depositing the compressive film and the tensile film is interchangeable. In some implementations, the compressive film has a first parabolic-shaped profile and the tensile film has a second parabolic-shaped profile that opens in a direction opposite the first parabolic-shaped profile. The compressive film and the tensile film collectively form the bow compensation layer. The bow compensation layer is flat or substantially flat. Such a film stacking technique in backside deposition minimizes IPD overlay impact without impacting chucking.

Thickness tuning of the one or more films in a bow compensation layer may be achieved by controlling precursor concentration adjacent to the bowed semiconductor substrate during deposition. In the present disclosure, precursor concentration adjacent to the bowed semiconductor substrate may be controlled by design features in a showerhead pedestal. Such design features may influence flow dynamics of the precursor from the showerhead pedestal. In some implementations, the showerhead pedestal may be divided into multiple zones, For example, precursor gas may be delivered in a first zone and dilution gas may be delivered in a second zone. This modulates the concentration of precursor gas adjacent to the bowed semiconductor substrate. In some implementations, the precursor gas may be delivered via a first supply tube and the dilution gas may be delivered via a second supply tube. Additionally or alternatively, a faceplate of the showerhead pedestal may have varying hole patterns (e.g., hole densities) among the zones of the showerhead pedestal. Additionally or alternatively, a geometric profile of the faceplate may be designed with varying gap distances from the showerhead pedestal to the bowed semiconductor substrate. The varying gap distances proceed along an x-axis or y-axis direction of the showerhead pedestal.

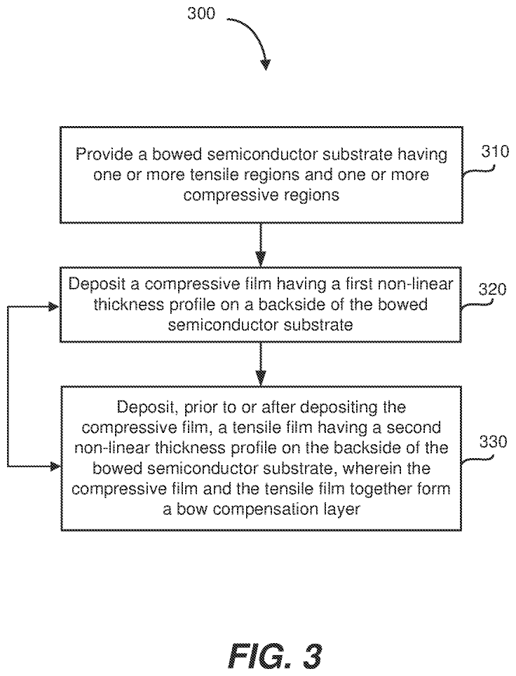

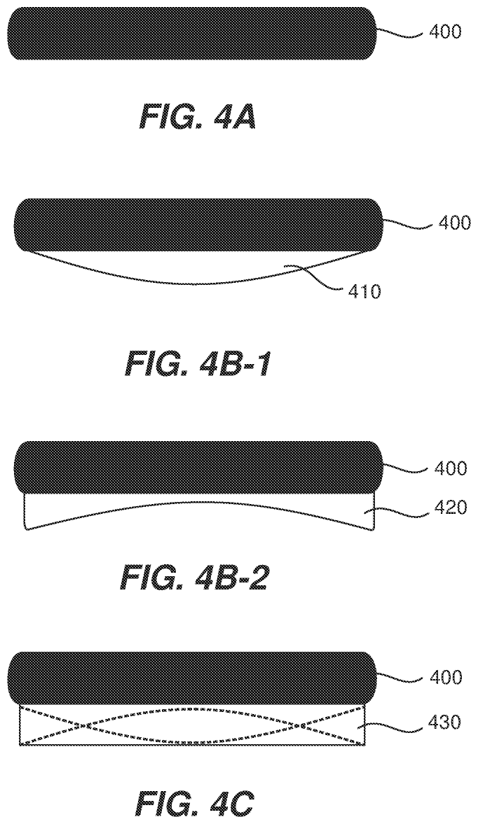

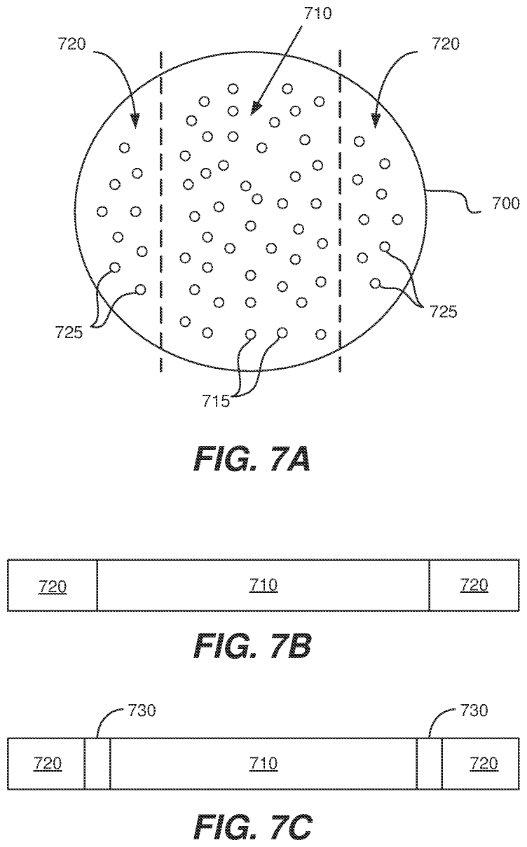

FIG. 3 illustrates a flow diagram of an example method of forming a bow compensation layer to mitigate asymmetric bowing in a bowed semiconductor substrate according to some implementations. The operations of a process 300 may be performed in different orders and/or with different, fewer, or additional operations. The operations of the process 300 may be described according to the various stages of forming a bow compensation layer in FIGS. 4A-4C. The operations of the process 300 may be performed using an apparatus for film deposition in FIG. 7A-7C, 9A-9B, or 10A-10D. In some implementations, the operations of the process 300 may be implemented, at least in part, according to software stored in one or more non-transitory computer readable media.

At block 310 of the process 300, a bowed semiconductor substrate having one or more tensile regions and one or more compressive regions is provided. A bowed semiconductor substrate refers to any semiconductor substrate that has a surface that deviates from a flat reference plane. In particular, a bowed semiconductor substrate has warpage that exceeds ±300 μm. The bowed semiconductor substrate may be provided in a process chamber for performing backside deposition. The bowed semiconductor substrate may be asymmetrically bowed. In some implementations, the bowed semiconductor substrate is saddle-shaped.

The substrate may be a silicon wafer, such as a 200-mm wafer. 300-mm wafer, or a 450-mm wafer, including wafers having one or more layers of material, such as dielectric, conducting, or semiconducting materials deposited on a frontside of the substrate. Some of the one or more layers may be patterned. Non-limiting examples of layers include dielectric layers and conducting layers such as silicon oxides, silicon nitrides, silicon carbides, metal oxides, metal nitrides, metal carbides, and metal layers. In various implementations, the substrate is patterned.

In some implementations, the bowed semiconductor substrate includes a patterned 3D-NAND structure and one or more etched trenches in the substrate.

The bowed semiconductor substrate may have a warpage of about ±1000 μm. In some implementations, the bowed semiconductor substrate has a warpage greater than about ±300 μm. In some implementations, the bowed semiconductor substrate has a warpage greater than about ±300 μm and less than about ±1000 μm. The warpage may occur at one or more localized regions of the bowed semiconductor substrate. The warpage may have different values between an x-axis warpage and y-axis warpage. The warpage may be a result of anisotropic stress distribution in the semiconductor substrate.

As used herein, tensile regions create localized tensile stress that induces warpage having positive values. Tensile regions cause localized concave bending of the semiconductor substrate. As used herein, compressive regions create localized compressive stress that induces warpage having negative values. Compressive regions cause localized convex bending of the semiconductor substrate. The one or more tensile regions and the one or more compressive regions are attributable to the one or more layers of materials on the substrate.

In some implementations, a center of the bowed semiconductor substrate has compressive stress and at least two opposing edges of the bowed semiconductor substrate has tensile stress. In some implementations, a center of the bowed semiconductor substrate has tensile stress and at least two opposing edges of the bowed semiconductor substrate has compressive stress. A stress profile in the x-axis direction of the bowed semiconductor substrate may be described by a parabolic or other non-linear function. A stress profile in the y-axis direction of the bowed semiconductor substrate may be described by a parabolic or other non-linear function. Specifically, the stress profile in the x-axis direction may be described by a polynomial function and the stress profile in the y-axis direction may be described by a polynomial function.

In some implementations, the bowed semiconductor substrate is provided in a process chamber for performing a deposition operation. The process chamber for performing the deposition operation may be configured for backside or frontside deposition. In some implementations, the process chamber is configured for backside deposition. In some implementations, backside deposition may be achieved by delivering process gases to a backside of the bowed semiconductor substrate from a bottom showerhead (the bottom showerhead of which may be referred to as a showerhead to the pedestal, showerhead pedestal, or a “shaped”) of the process chamber. In some implementations, the backside of the bowed semiconductor substrate is not patterned. Showerheads generally described herein refer to bottom showerheads or showerhead pedestals for delivering gases to a backside of the bowed semiconductor substrate.

FIG. 4A shows a cross-sectional schematic illustration of a bowed semiconductor substrate. Though not visibly shown, a semiconductor substrate 100 is bowed. A frontside of the semiconductor substrate 400 may be patterned with structures (e.g., nanostructures) leading to anisotropic stress distribution in the semiconductor substrate 400. The anisotropic stress distribution may be characterized by a polynomial function such as a parabolic function in one or both of the x-axis and y-axis directions, where the x-axis and y-axis define a reference plane of the semiconductor substrate 400. The semiconductor substrate 400 may be asymmetrically bowed. For example, the semiconductor substrate 400 may be saddle-shaped. The semiconductor substrate 400 may have a warpage equal to or greater than about +300 μm or equal to or less than about −300 μm in one or both of the x-axis and y-axis directions. The semiconductor substrate 400 may be provided in a process chamber for deposition such as a process chamber for backside deposition.

Returning to FIG. 3, at block 320 of the process 300, a compressive film is deposited having a first non-linear thickness profile on a backside of the bowed semiconductor substrate. A compressive film refers to a thin film having an intrinsic compressive stress. The compressive film may have an intrinsic compressive stress such as a negative stress value of up to −4000 MPa. A thickness profile is presented along an axial direction (e.g., x-axis or y-axis direction) of the film. A non-linear thickness profile is characterized by any deviation from linearity of the film along the axial direction. The non-linear thickness profile may be characterized by a parabolic function or other polynomial function. For instance, the non-linear thickness profile may be a first parabolic-shaped profile that opens upwards or downwards. Where the first parabolic-shaped profile opens upwards, the compressive film is thicker at the edges of the bowed semiconductor substrate and tapers at the center of the bowed semiconductor substrate. Where the first parabolic-shaped profile opens downwards, the compressive film is thicker at the center of the bowed semiconductor substrate and tapers at the edges. Depending on the warpage in the bowed semiconductor substrate, the compressive film may have a non-linear thickness profile in one or both of the x-axis and y-axis directions,

Depositing the compressive film according to a non-linear thickness profile may occur by controlling precursor concentration from a showerhead pedestal. The precursor concentration may be controlled to vary across the backside of the semiconductor substrate. Specifically, thickness control may be achieved by controlling precursor concentration adjacent to the backside of the bowed semiconductor substrate during deposition. More precursor for depositing the compressive film is flowed in the one or more compressive regions. Less or no precursor for depositing the compressive film is flowed in the one or more tensile regions. Controlling precursor concentration to vary across the backside of the semiconductor substrate may occur by influencing flow dynamics from the showerhead pedestal. Precursor concentration may vary along one or both of an x-axis and y-axis directions of the bowed semiconductor substrate.

In some implementations, the compressive film may be a compressive silicon oxide, compressive silicon nitride, compressive silicon, or compressive carbon film. In some implementations, the compressive film is a compressive silicon oxide or compressive silicon nitride film. The selection of precursors and process conditions can be used to tune the stress of the compressive film. In some implementations, the compressive film is deposited on the backside of the bowed semiconductor substrate using any suitable deposition technique such as plasma enhanced chemical vapor deposition (PECVD), chemical vapor deposition (CVD), plasma enhanced atomic layer deposition (PEALD), or atomic layer deposition (ALD). For example, the compressive film is deposited using PECVD.

“Silicon oxide” is referred to herein as including chemical compounds including silicon and oxygen atoms, including any and all stoichiometric possibilities for SiₓO_{y}, including integer values of x and y and non-integer values of x and y. “Silicon nitride” is referred to herein as including any and all stoichiometric possibilities for SiₓN_{y}, including integer values of x and y and non-integer values of x and y; for example, a ratio X:Y may be 3:4.

In some implementations, a compressive silicon oxide film may be deposited using a mixture of a silicon-containing precursor and an oxygen-containing reactant. Examples of silicon-containing precursors include but are not limited to silanes and tetraethyl orthosilicate (TEOS). Examples of oxygen-containing reactants include but are not limited to oxygen and nitrous oxide. In PECVD, the silicon-containing precursor may react with the oxygen-containing reactant exposed to plasma to form the compressive silicon oxide film. An inert gas such as helium may be present.

In some implementations, a compressive silicon nitride film may be deposited using a mixture of a silicon-containing precursor and a nitrogen-containing reactant. Examples of silicon-containing precursors include but are not limited to silanes and TEOS. Examples of nitrogen-containing reactants include but are not limited to nitrogen and ammonia. In PECVD, the silicon-containing precursor may react with the nitrogen-containing reactant exposed to plasma to form the compressive silicon nitride film. An inert gas such as helium may be present.

The selection of a silicon-containing precursor and reactants as well as the plasma type (dual or single frequency) and process conditions may affect the stress of the film being deposited. In some implementations, a flow rate of the silicon-containing precursor relative to other gases flowed during deposition may tune the stress. For example, in deposition of compressive silicon nitride, increase in silane flow may decrease stress, making what would be a compressive silicon nitride film less compressive. That is, in some implementations, increase in silane flow causes the deposited film to be less compressive. In some implementations, substrate temperature may be tuned to modulate stress in the compressive film. For example, higher temperatures may be used to achieve higher stress or increase a stability of the film being deposited. In some implementations, substrate temperature for deposition on the backside of the bowed semiconductor substrate is equal to or greater than about 250° C. or between about 300° C. and about 550° C.

The compressive film is used to compensate the one or more compressive regions of the bowed semiconductor substrate. In some implementations, an average thickness of the compressive film is between about 20 nm and about 2000 nm or between about 30 nm and about 1500 nm. A thickness of the compressive film can affect the wafer bow of the compressive film to compensate asymmetric bowing in the bowed semiconductor substrate. Accordingly, a non-linear thickness profile in the compressive film achieves a desired wafer bow that compensates the one or more compressive regions of the bowed semiconductor substrate. In other words, portions of the compressive film having greater thickness may induce more wafer bow and portions of the compressive film having less thickness may induce less wafer bow.

FIG. 4B-1 shows a cross-sectional schematic illustration of a compressive film with a parabolic thickness profile deposited on a backside of the bowed semiconductor substrate. The compressive film 410 may be deposited by PECVD, The compressive film 410 may be a compressive silicon oxide, compressive silicon nitride, compressive silicon, or compressive carbon film. The compressive film 410 may be thicker at a center of the bowed semiconductor substrate 400 than at opposite edges of the bowed semiconductor substrate 400. Though the compressive film 410 in FIG. 4B-1 is shown having a parabolic thickness profile, the thickness profile may match or substantially match a polynomial function such as a second order or third order polynomial function. The parabolic thickness profile of the compressive film 410 opens downwards. The parabolic thickness profile of the compressive film 410 is depicted along an x-axis or y-axis direction.

Returning to FIG. 3, at block 330 of the process 300, a tensile film having a second non-linear thickness profile is deposited on the backside of the bowed semiconductor substrate prior to or after depositing the compressive film. The compressive film and the tensile film together form a bow compensation layer for mitigating bowing in the bowed semiconductor substrate. A tensile film refers to a thin film having an intrinsic tensile stress. The tensile film may have an intrinsic tensile stress such as a positive stress value of up to +4000 MPa. The non-linear thickness profile may be characterized by a parabolic function or other polynomial function. Depending on the warpage in the bowed semiconductor substrate, the tensile film may have a non-linear thickness profile in one or both of the x-axis and y-axis directions. In some implementations, the non-linear thickness profile may be a second parabolic-shaped profile that opens downwards or upwards. In some implementations, the second parabolic-shaped profile opens in a direction opposite the first parabolic-shaped profile. As a result, the bow compensation layer is flat or substantially flat. A bow compensation layer refers to the one or more films deposited on the backside of the backside of the semiconductor to correct or compensate wafer bowing in the semiconductor substrate. As used herein, the term “substantially flat” throughout this disclosure refers to wafer bowing or deviations from a flat reference plane that is less than 100 μm in either the x-axis or y-axis direction. Having a flat or substantially fiat bow compensation layer reduces IPD, where low IPD reduces overlay impact, ensures proper wafer chucking, and avoids defocusing.

Depositing the tensile film according to a non-linear thickness profile may occur by controlling precursor concentration from a showerhead. pedestal. The precursor concentration may be controlled to vary across the backside of the semiconductor substrate.. In particular, thickness control may be achieved by controlling precursor concentration adjacent to the backside of the bowed semiconductor substrate during deposition. More precursor for depositing the tensile film is flowed in the one or more tensile regions. Less or no precursor for depositing the tensile film is flowed in the one or more compressive regions. Controlling precursor concentration to vary across the backside of the bowed semiconductor substrate may occur by influencing flow dynamics from the showerhead pedestal. Precursor concentration may vary along one or both of an x-axis and y-axis directions of the bowed semiconductor substrate.

In some implementations, the tensile film may be a tensile silicon oxide, tensile silicon nitride, tensile silicon, or tensile carbon film. In some implementations, the tensile film is a tensile silicon oxide or tensile silicon nitride film. The selection of precursors and process conditions can be used to tune the stress of the tensile film. In some implementations, the tensile film is deposited on the backside of the bowed semiconductor substrate using any suitable deposition technique such as PECVD, CND, PEALD, or ALD. For example, the tensile film is deposited using PECVD.

In some implementations, a tensile silicon oxide film may be deposited using a mixture of a silicon-containing precursor and an oxygen-containing reactant. In PECVD, the silicon-containing precursor may react with the oxygen-containing reactant exposed to plasma to form the tensile silicon oxide film. An inert gas such as helium may be present.

In some implementations, a tensile silicon nitride film may be deposited using a mixture of a silicon-containing precursor and a nitrogen-containing reactant. In PECVD, the silicon-containing precursor may react with the nitrogen-containing reactant exposed to plasma to form the tensile silicon nitride film. An inert gas such as helium may be present.

The selection of a silicon-containing precursor and reactants as well as the plasma type (dual or single frequency) and process conditions may affect the stress of the film being deposited. In some implementations, a flow rate of the silicon-containing precursor relative to other gases flowed during deposition may tune the stress. In some implementations, substrate temperature may be tuned to modulate stress in the tensile film. For example, higher temperatures may be used to achieve higher stress or increase a stability of the film being deposited. In some implementations, substrate temperature for deposition on the backside of the bowed semiconductor substrate is equal to or greater than about 250° C. or between about 300° C. and about 550° C.

The tensile film is used to compensate the one or more tensile regions of the bowed

semiconductor substrate. In some implementations, an average thickness of the tensile film is between about 20 nm and about 2000 nm or between about 30 nm and about 1500 nm. A thickness of the tensile film can affect the wafer bow of the tensile film to compensate asymmetric bowing in the bowed semiconductor substrate, Accordingly, a non-linear thickness profile in the tensile film achieves a desired wafer bow that compensates the one or more tensile regions of the bowed semiconductor substrate. In other words, portions of the tensile film having greater thickness may induce more wafer bow and portions of the tensile film having less thickness may induce less wafer bow.

FIG. 4B-2 shows a cross-sectional schematic illustration of a tensile film with a parabolic thickness profile deposited on a backside of the bowed semiconductor substrate. The tensile film 420 may be deposited by PECVD. The tensile film 420 may be a tensile silicon oxide, tensile silicon nitride, tensile silicon, or tensile carbon film. The tensile film 420 may be thicker at opposite edges of the bowed semiconductor substrate 400 than at a center of the bowed semiconductor substrate 400. Though the tensile film 420 in FIG. 4B-2 is shown having a parabolic thickness profile, the thickness profile may match or substantially match a polynomial function such as a second order or third order polynomial function. The parabolic thickness profile of the tensile film 420 opens upwards. The parabolic thickness profile of the tensile film 420 is depicted along an x-axis or y-axis direction.

Returning to FIG. 3, block 320 and block 330 for depositing the compressive film and the tensile film may occur interchangeably. In some implementations, the compressive film may be deposited first followed by the tensile film. In some other implementations, the tensile film may be deposited first followed by the compressive film. The compressive film and the tensile film are stacked to achieve a flat or substantially flat surface. This flatness may result from the compressive film having a first non-linear thickness profile different than the tensile film having a second non-linear thickness profile.

The bow compensation layer is formed by stacking multiple films, i.e., the compressive film and the tensile film, where the bow compensation layer has a non-linear stress profile. The non-linear stress profile of the bow compensation layer may be largely characterized by polynomial function such as a parabolic function. In some implementations, additional films or layers may be stacked on the compressive film and tensile film for achieving a desired stress profile in the bow compensation layer. In some implementations, the bow compensation layer is removed. For instance, the bow compensation layer is removed in further downstream processing operations.

FIG. 4C shows a cross-sectional schematic illustration of a bow compensation layer formed on the backside of the bowed semiconductor substrate. The bow compensation layer 430 comprises the compressive film 410 and the tensile film 420 stacked on one another. By stacking the compressive film 410 and the tensile film 420, the bow compensation layer 430 achieves a fiat or substantially fiat surface. Because the compressive film 410 and the tensile film 420 open in opposite directions, combining the thickness profiles of the compressive film 410 and the tensile film 420 forms a flat or substantially flat profile. Different regions of the bow compensation layer 430 have different stress values to locally modulate stress. The stress variation in the bow compensation layer 430 may be characterized by a polynomial function such as a parabolic function. Consequently, the bow compensation layer 430 serves to mitigate asymmetric bowing in the bowed semiconductor substrate 400. Prior to depositing the bow compensation layer 430, the bowed semiconductor substrate 400 may have a warpage equal to or greater than about +300 μm or equal to or less than about −300 μm in one or both of the x-axis and y-axis directions. After depositing the bow compensation layer 430, the bowed semiconductor substrate 400 may have a warpage between about −300 μm and about +300 μm in both the x-axis and the y-axis directions. In some implementations, the bowed semiconductor substrate 400 may have a warpage between about −100 μm and about +100 μm in both the x-axis and the y-axis directions after depositing the bow compensation layer 430.

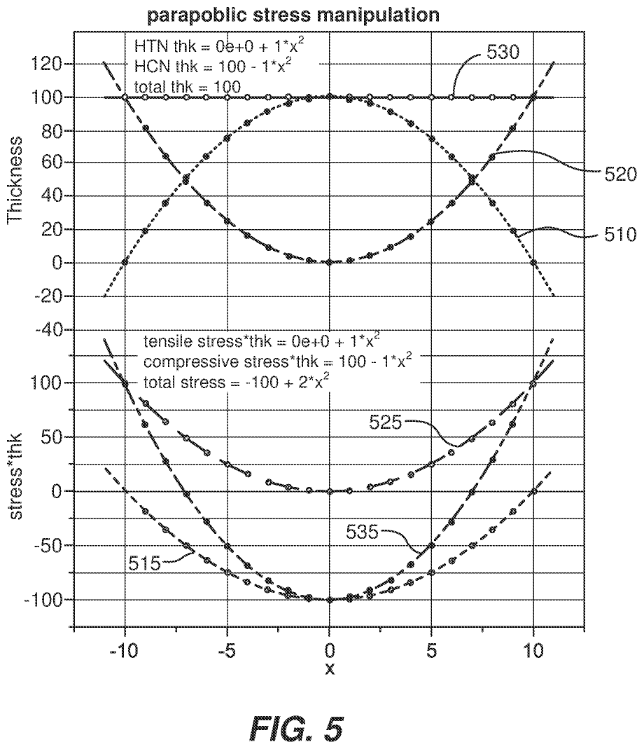

FIG. 5 shows a graph illustrating a thickness profile and a stress profile for each of (i) a compressive film, (ii) a tensile film, and (iii) a bow compensation layer that combines the compressive film and the tensile film according to some implementations. An upper portion of the graph measures a thickness profile as a function of position along the x-axis direction of the bowed semiconductor substrate. A lower portion of the graph measures a stress profile as a function of position along the x-axis direction of the bowed semiconductor substrate. Values in the stress profile are calculated as product values of stress multiplied by film thickness. The product value of stress multiplied by film thickness correlates with wafer bowing.

As shown in FIG. 5, a first thickness profile 510 of a highly compressive film is depicted as a parabolic-shaped curve. The thickness changes as a polynomial function, where the thickness in the first thickness profile 510 increases parabolically towards the center of the bowed semiconductor substrate and parabolically decreases towards the edges of the bowed semiconductor substrate. A second thickness profile 520 of a highly tensile film is depicted as a parabolic-shaped curve. The thickness changes as a polynomial function, where the thickness in the second thickness profile 520 increases parabolically towards the edges of the bowed semiconductor substrate and decreases parabolically towards the center of the bowed semiconductor substrate. When the highly compressive film and the highly tensile film are combined to form a third thickness profile 530, the resulting third thickness profile 530 is depicted as a flat or uniform line. A thickness in the third thickness profile 530 is uniform across the x-axis dimension of the bowed semiconductor substrate.

As shown in FIG. 5, a first stress profile 515 of the highly compressive film is depicted as a parabolic-shaped curve. As the thickness parabolically increases towards the center of the bowed semiconductor substrate, the stress parabolically becomes more negative. As the thickness parabolically decreases at the edges of the bowed semiconductor substrate, the stress parabolically becomes less negative and eventually reaches zero. A second stress profile 525 of the highly tensile film is depicted as a parabolic-shaped curve. As the thickness parabolically increases towards the edges of the bowed semiconductor substrate, the stress parabolically increases. As the thickness parabolically decreases towards the center of the bowed semiconductor substrate, the stress parabolically decreases and eventually reaches zero. A third stress profile 535 is calculated when the total stress is measured for both the highly compressive film and the highly tensile film. Towards the edges of the bowed semiconductor substrate, the stress parabolically increases. Towards the center of the bowed semiconductor substrate, the stress parabolically becomes more negative.

A thickness profile of a compressive or tensile film is modulated by controlling a concentration of precursor gas delivered adjacent to a bowed semiconductor substrate. This concentration of precursor gas is controlled by varying how much precursor gas is flowed from a showerhead pedestal along one or both of the x-axis and y-axis directions. Hardware components of the showerhead pedestal may be engineered to vary precursor gas distribution from the showerhead pedestal.

The present disclosure relates to a showerhead pedestal for modulating precursor gas distribution adjacent to a backside of a semiconductor substrate. The precursor gas distribution adjacent to the semiconductor substrate may match or substantially match a desired thickness profile that is described by a polynomial function. The polynomial function may be a second order or higher order polynomial function. Various designs of showerhead pedestals for controlling precursor gas distribution are shown in FIGS. 7A-7C, 8A-8B, 9A-9B, and 10A-10D. In some implementations, the showerhead precursor may be divided into multiple zones by baffles in a plenum volume of the showerhead pedestal, where precursor gas is flowed in at least a first zone and dilution gas is flowed in at least a second zone.

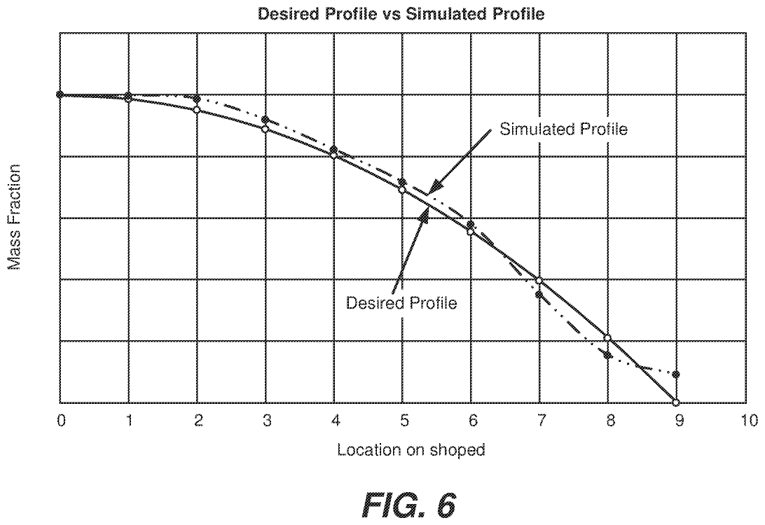

FIG. 6 shows a graph illustrating a desired profile and a simulated profile of gas reactant flowing from a showerhead pedestal to a backside of a bowed semiconductor substrate according to some implementations. Mass flow of gas reactant from a showerhead pedestal may be measured as a function of location on the showerhead pedestal along an axial direction (x-axis or y-axis direction). A desired profile follows a parabolic curve, with maximum mass flow at a center (0 mm) of the showerhead pedestal and with zero mass flow at an edge (140 mm) of the showerhead pedestal. A simulated profile may not perfectly match the desired profile but may substantially match the desired profile. An observed or simulated curve “substantially matches” a parabolic or polynomial curve based upon fitting the observed curve to a polynomial function and taking residuals from the fitting to determine how good the matching is. As used herein, when the R-square (R²) measurement of the residuals is equal to or greater than about 0.95, then the observed curve can be deemed to “substantially match” the polynomial function. A showerhead pedestal of the present disclosure can achieve a gas reactant mass flow profile that substantially matches a parabolic or polynomial function.

A showerhead or showerhead pedestal is used to distribute process gases to a semiconductor substrate in a process chamber. The showerhead includes a backplate and a faceplate with a plurality of gas distribution holes that lead to outside the showerhead. Generally, a faceplate is a block of material(s) that defines an outer body of the showerhead that faces towards an interior of a process chamber. Gas distribution holes refer to openings that permit gas to be delivered from the showerhead or showerhead pedestal to a semiconductor substrate. A backplate is a block of material(s) that defines the outer body of the showerhead that faces away from the interior of the process chamber. Each of the backplate and the faceplate may be a cylindrical shape or disk shape. The backplate and the faceplate may be connected to one another or removably attached to one another. The backplate and the faceplate may enclose a volume in the showerhead referred to as a plenum volume. A plenum volume is a space between and hounded by the backplate and the faceplate. One or more gas inlets may be coupled to the backplate to deliver process gases into the plenum volume. In some instances, the one or more gas inlets include a stem connected to the backplate. Process gases in the plenum volume exit the showerhead by flowing out of the plurality of gas distribution holes. The basic architecture of a showerhead as described herein may apply to each of the showerhead pedestals described in FIGS. 7A-7C, 8A-8B, 9A-9B, and 10A-10D. A showerhead pedestal is a showerhead that is configured to deliver process gases to a backside of a semiconductor substrate.

In some implementations, a showerhead pedestal of the present disclosure may vary precursor gas distribution by being divided into at least two zones. In some embodiments, each of the at least two zones may have varying hole patterns. Each zone may be characterized by one or more of: different number or different density of holes, holes of different diameters, holes of different geometries, and different arrangement or different layout of holes. Examples of such showerhead pedestals are illustrated schematically in FIGS. 7A-7C.

FIG. 7A shows a top view of a schematic of an example showerhead pedestal with various hole patterns in at least two zones according to some implementations. A faceplate 700 of the showerhead pedestal is divided into a first zone 710 and a second zone 720. The first zone 710 extends through a center of the faceplate 700 and includes a plurality of first holes 715 arranged according to a first pattern. The second zone 720 covers two opposite edges of the faceplate 700 to the right and to the left of the first zone 710, where the second zone 720 includes a plurality of second holes 725 arranged according to a second pattern. For example, the plurality of first holes 715 in the first zone 710 may have a different density than the plurality of second holes 725 in the second zone 720.

In some implementations, the showerhead pedestal of FIG. 7A divided into at least two zones distributes precursor gas that varies in concentration adjacent to a semiconductor substrate. In some instances, the showerhead pedestal divided into at least two zones can distribute precursor gas adjacent to the semiconductor substrate in a gas flow profile that matches or substantially matches a polynomial function (e.g., parabolic function). A first gas such as a reactant gas for depositing a highly compressive film may be configured to flow out of the plurality of first holes 715 in the first zone 710 without flowing from the plurality of second holes 725 in the second zone 720. A second gas such as a reactant gas for depositing a highly tensile film may be configured to flow out of the plurality of second holes 725 in the second zone 720 without flowing from the plurality of first holes 715 in the first zone 710. That way, a thickness profile of the highly compressive film is larger at the center than at the two opposite edges, and a thickness profile of the highly tensile film is larger at the two opposite edges than at the center. It will be understood that the reactant gas for depositing the highly compressive film may be swapped to flow out of the plurality of second holes 725 in the second zone 720, and the reactant gas for depositing the highly tensile film may be swapped to flow out of the plurality of first holes 715 in the first zone 710.

FIG. 7B shows a side view of a schematic of the example showerhead pedestal with differing hole densities in at least two zones according to some implementations. Differing hole densities between the first zone 710 and the second zone 720 can modulate mass flow of gas from each of the zones. In some implementations, flow restriction in each zone may be obtained by adjusting hole density of discrete holes in the faceplate. In some other implementations, flow restriction in each zone may be obtained by adjusting porosity of a porous material.

FIG. 7C shows a side view of a schematic of an example showerhead pedestal with dead zones in between at least two zones according to some implementations. A dilution gas may be flowed simultaneous with a reactant gas for depositing a compressive or tensile film. The reactant gas may be flowed through the first zone 710 and the dilution gas may be flowed through the second zone 720, or vice versa. The dilution gas reduces (i.e., dilutes) a concentration of the reactant gas adjacent to the semiconductor substrate. Specifically, more dilution gas at the edges of the semiconductor substrate reduces a concentration of reactant gas at the edges of the semiconductor substrate, or more dilution gas at a center of the semiconductor substrate reduces a concentration of reactant gas at the center of the semiconductor substrate. In FIG. 7C, dead zones 730 separate and physically divide the first zone 710 from the second zone 720. This limits mixing of the dilution gas and the reactant gas in the showerhead pedestal until the gases are delivered out of the showerhead pedestal.

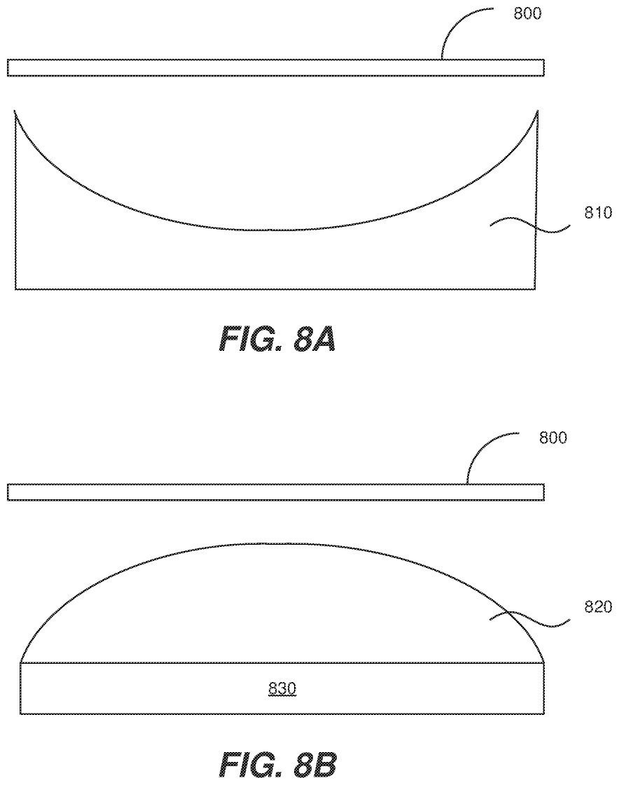

In some implementations, a showerhead pedestal of the present disclosure has a concave, convex, or other non-uniform shape. Such shapes provide varying gap distances between the showerhead pedestal and the semiconductor substrate as measured from an outer surface of the showerhead pedestal. The concave, convex, or other non-uniform shape of the showerhead pedestal may be defined by a shape of the faceplate and/or plenum volume. Larger spacing generally reduces deposition rate, and smaller spacing generally increases deposition rate. Without being limited by any theory, larger spacing generally reduces plasma density and smaller spacing generally increases plasma density. By varying the gap distances at different points across the semiconductor substrate, deposition uniformity in a PECVD process is modulated across the semiconductor substrate. Examples of such showerhead pedestals are illustrated schematically in FIGS. 8A-8B.

FIG. 8A shows a side view of a schematic of an example concave showerhead pedestal to provide varying gap distances to a backside of a bowed semiconductor substrate according to some implementations. A faceplate 810 of the showerhead pedestal may be concave-shaped so that the gap distance parabolically increases towards a center of a semiconductor substrate 800 and decreases towards opposite edges of the semiconductor substrate 800. By way of an example, a gap distance from the faceplate 810 of the showerhead pedestal may be about 14 mm to the center of the semiconductor substrate 800, and a gap distance from the faceplate 810 of the showerhead pedestal may be about 2 mm to the opposite edges of the semiconductor substrate 800. Hence, during a PECVD process, a thickness profile of deposited film may be substantially parabolic so that more film is deposited at the opposite edges of the semiconductor substrate 800 than at the center of the semiconductor substrate 800.

FIG. 8B shows a side view of a schematic of an example convex showerhead pedestal to provide varying gap distances to a backside of a bowed semiconductor substrate according to some implementations. A faceplate 820 of the showerhead pedestal may be convex-shaped so that the gap distance parabolically decreases towards a center of a semiconductor substrate 800 and increases towards opposite edges of the semiconductor substrate 800. It will be understood that one or both of the faceplate 820 and a plenum volume 830 may be convex-shaped. By way of an example, a gap distance from the faceplate 820 of the showerhead pedestal may be about 14 mm to opposite edges of the semiconductor substrate 800, and a gap distance from the faceplate 820 of the showerhead pedestal may be about 2 mm to a center of the semiconductor substrate 800. As a result, during a PECVD process, a thickness profile of deposited film may be substantially parabolic so that more film is deposited at the center of the semiconductor substrate 800 than at the opposite edges of the semiconductor substrate 800.

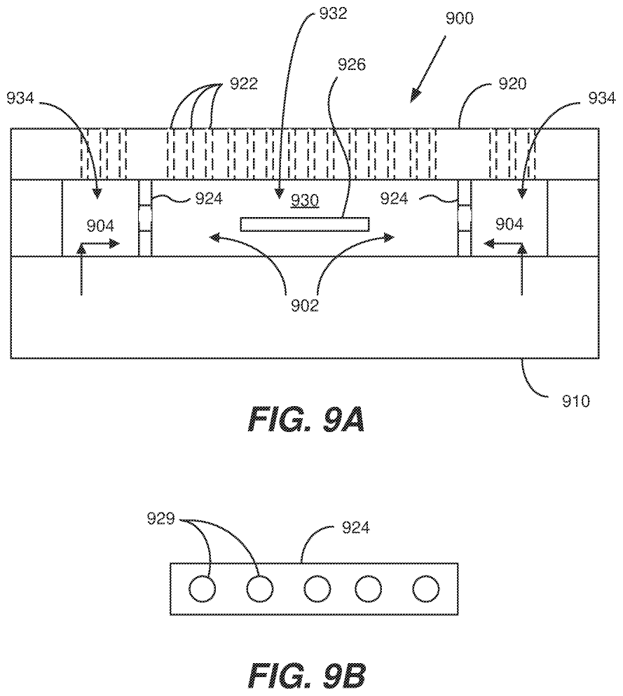

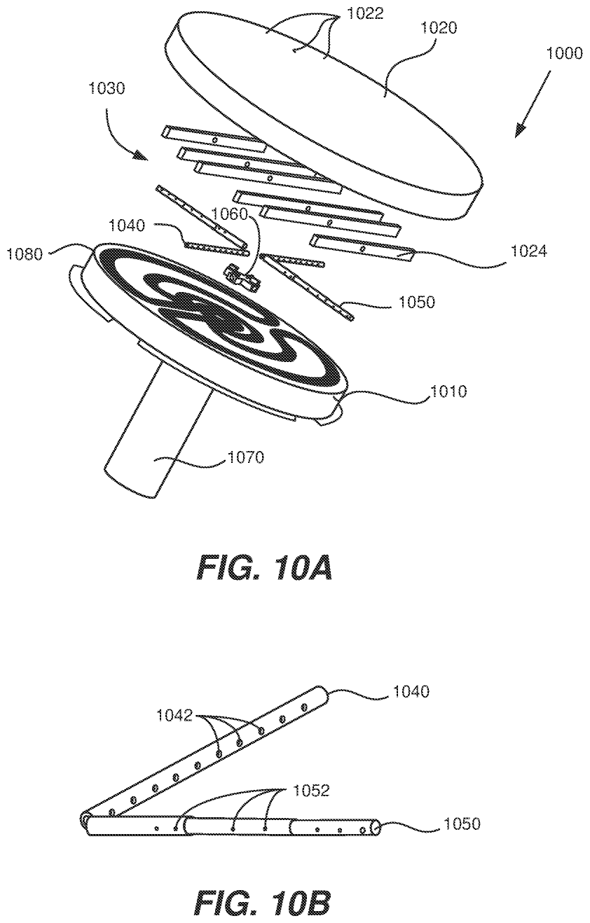

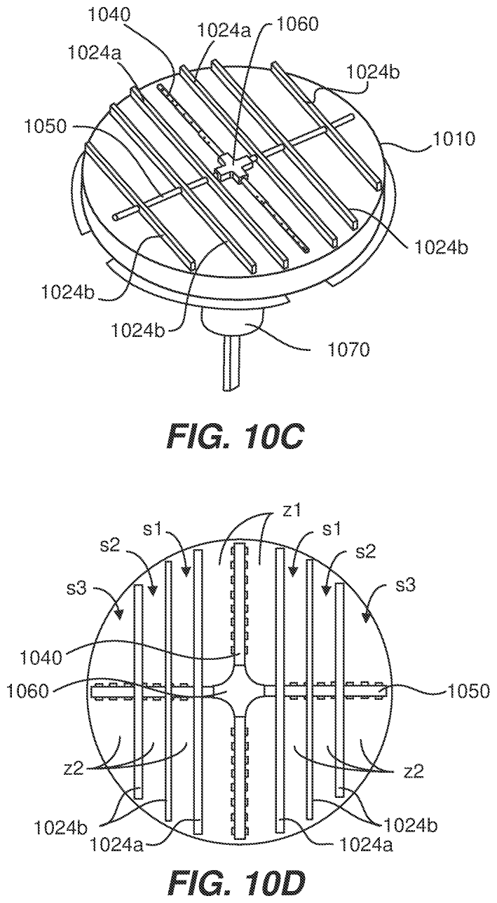

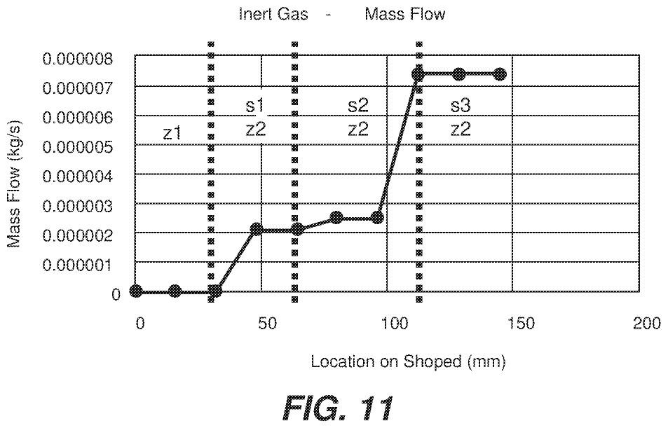

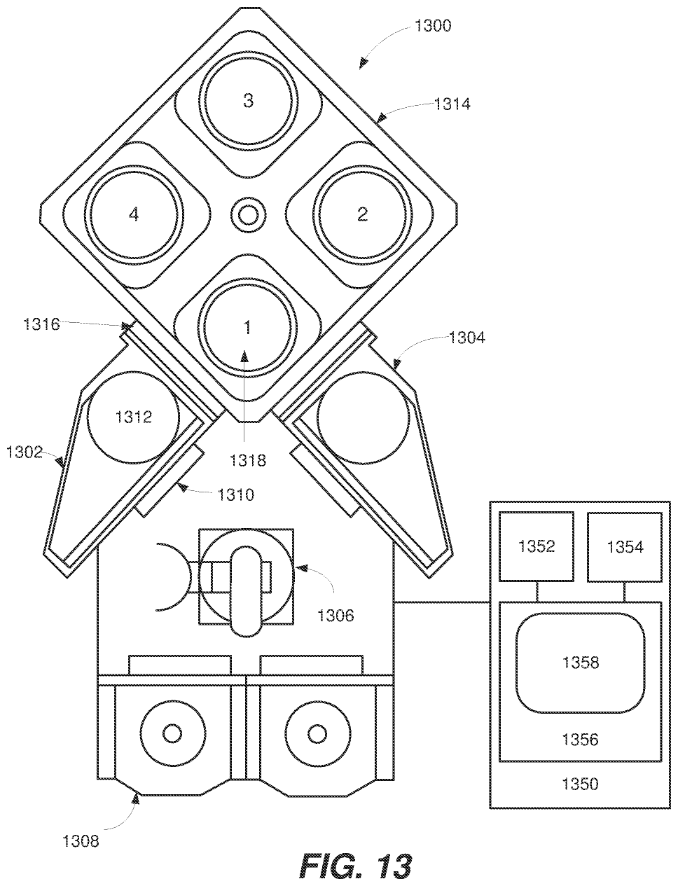

In some implementations, a showerhead pedestal of the present disclosure is divided into at least two zones. The showerhead pedestal modulates a concentration of precursor gas delivered across a backside of a semiconductor substrate by flowing dilution gas in at least one of the zones. Flowing dilution gas in certain zones or regions adjacent to the semiconductor substrate will dilute or otherwise limit a concentration of precursor gas in the regions adjacent to the semiconductor substrate. Examples of dilution gas include nitrogen gas (N₂) or inert gas species such as helium (He), argon (Ar), neon (Ne), or xenon (Xe). In some implementations, the dilution gas can be flowed to mix with the precursor gas in the plenum volume. In some implementations, the dilution gas can be flowed to mix with the precursor gas in an environment adjacent to the semiconductor substrate without mixing in the plenum volume. Mixing with the dilution gas may provide a precursor gas flow profile that matches or substantially matches a parabolic or other polynomial function. Examples of such showerhead pedestals are illustrated schematically in FIGS. 9A-9B and 10A-10D. The showerhead pedestals of the present disclosure may be integrated in a process chamber or tool for performing backside deposition operations. The process chamber or tool may include a system controller for communicating instructions with the showerhead pedestal for performing the backside deposition operations. Details regarding a system controller are described with respect to FIG. 13.

FIG. 9A shows a side view of a schematic of an example showerhead pedestal having a plenum volume separated into a first zone for delivering reactant gas and a second zone for delivering dilution gas according to some implementations. A showerhead pedestal 900 includes a faceplate 920 having a plurality of gas distribution holes 922. The showerhead pedestal 900 further includes a backplate 910 opposite the faceplate 920. A plenum volume 930 is defined as a space between the backplate 910 and the faceplate 920. The faceplate 920 is configured to face a backside of a bowed semiconductor substrate. One or more gas inlets (not shown) are coupled to the backplate 910 for delivering a first gas 902 and a second gas 904 into the plenum volume 930. One or more baffles 921 are positioned in the plenum volume 930 to divide the plenum volume 930 into a plurality of zones 932, 931, As used herein, a baffle refers to a block of materials) positioned within a plenum volume of a showerhead to block, restrict, or redirect gas flow in the plenum volume. In FIG. 9A, the one or more baffles 924 separate the plenum volume 930 into a first zone 932 spanning a central region of the showerhead pedestal 900 and a second zone 934 spanning an edge region of the showerhead pedestal 900. The edge region of the showerhead pedestal 900 may include at least two opposite edges of the showerhead pedestal 900. A height of each of the one or more baffles 924 may extend a gap distance between the backplate 910 and the faceplate 920. This limits gas flow between the first zone 932 and the second zone 934. In the showerhead pedestal 900 of FIG. 9A, the first gas 902 is flowed into the first zone 932 of the plenum volume 930 and the second gas 904 is flowed into the second zone 934 of the plenum volume 930. In some implementations, a central baffle 926 is positioned in the plenum volume 930 to spread a flow of the first gas 902. That way, the flow of the first gas 902 is more uniformly distributed in the first zone 932 of the plenum volume 930 and does not jet out of the center of the plenum volume 930.

FIG. 9B shows a side view of a schematic of an example baffle separating the first zone from the second zone in the showerhead pedestal of FIG. 9A. Though the one or more baffles 924 are used to separate zones 932, 934 in the showerhead pedestal 900, each of the one or more baffles 924 may have holes 929 to permit mixing of the first gas 902 with the second gas 904 in the plenum volume 930. The holes 929 may be arranged along the one or more baffles 924 according to any suitable arrangement, number, and geometry. The holes 929 permit fluid communication between the zones 932, 934 in the showerhead pedestal 900. As used herein, fluid communication refers to condition that permits fluid flow between regions or components.

In some implementations, the first gas 902 is a precursor gas and the second gas 904 is a dilution gas. Example precursor gases include silicon-containing gases, oxygen-containing gases, and nitrogen-containing gases for depositing compressive or tensile films. Example dilution gases include nitrogen gas and inert gases. By flowing dilution gas from the edges of the plenum volume 930, mass flow of the precursor gas is greatest near a center of the plenum volume 930 and gradually decreases towards the edges of the plenum volume 930. Mass flow of the precursor gas out of the showerhead pedestal 900 may match or substantially match a parabolic function or other polynomial function. Accordingly, a thickness profile of a compressive or tensile film may match or substantially match a parabolic function or other polynomial function.

In some implementations, the first gas 902 is a dilution gas and the second gas 904 is a precursor gas. By flowing dilution gas from the center of the plenum volume 930, mass flow of the precursor gas is greatest at the edges of the plenum volume 930 and gradually decreases towards the center of the plenum volume. Mass flow of the precursor gas out of the showerhead pedestal 900 may match or substantially match a parabolic function or other polynomial function. Accordingly, a thickness profile of a compressive or tensile film may match or substantially match a parabolic function or other polynomial function.

In some other implementations, the one or more baffles 924 in the plenum volume 930 may be without holes to prohibit mixing between the first gas 902 and the second gas 904. The first gas 902 and the second gas 904 mix after flowing out of the plurality of gas distribution holes 922 of the faceplate 920. In addition or in the alternative, the showerhead pedestal 900 may be without a central baffle 926. An example showerhead pedestal without holes in the one or more baffles 924 to prohibit mixing and without a central baffle 926 is illustrated schematically in FIGS. 10A-10D.

FIG. 10A shows a perspective view of various components of an example multi-zone showerhead pedestal including a first supply tube delivering a first gas to a first zone and a second supply tube delivering a second gas to a second zone according to some implementations. As used herein, a supply tube is any hollow member that extends longitudinally within the plenum volume for delivering a gas into the plenum volume. The components of a multi-zone showerhead pedestal 1000 are presented as discrete components prior to assembly for the sake of illustration. The multi-zone showerhead pedestal 1000 includes a faceplate 1020 having a plurality of gas distribution holes 1022. The faceplate 1020 is configured to face a backside of a bowed semiconductor substrate. The multi-zone showerhead pedestal 1000 further includes a backplate 1010 opposite the faceplate 1020. Though not perceptibly illustrated in FIG. 10A, a plenum volume 1030 is a defined as a space between the backplate 1010 and the faceplate 1020 when the multi-zone showerhead pedestal 1000 is assembled. The multi-zone showerhead pedestal 1000 may further include a stem 1070 connected to the backplate 1010, where the stem 1070 includes gas delivery lines for delivering one or more process gases through the backplate 1010.

In some implementations, the multi-zone showerhead pedestal 1000 may optionally include one or more heaters 1080 for heating the multi-zone showerhead pedestal 1000. The one or more heaters 1080 may be coupled to the backplate 1010. In some implementations, the one or more heaters 1080 may be positioned to provide localized heating in different zones of the backplate 1010.

The multi-zone showerhead pedestal 1000 may further include a first supply tube 1040 in the plenum volume 1030 and a second supply tube 1050 in the plenum volume 1030. In some implementations, the multi-zone showerhead pedestal 1000 further includes a center plug 1060 in the plenum volume 1030 and in fluid communication with each of the first supply tube 1040 and the second supply tube 1050. As used herein, fluid communication refers to condition that permits fluid flow between regions or components. Process gases may be delivered through gas delivery lines of the stem 1070 and distributed into the first supply tube 1040 and the second supply tube 1050 via the center plug 1060. The center plug 1060 acts like a splitter so that a first gas is distributed to the first supply tube 1040 and a second gas is distributed to the second supply tube 1050. The center plug 1060 also serves to split each of the first supply tube 1040 and the second supply tube 1050 into two segments. As shown in FIG. 10B, the first supply tube 1040 includes a plurality of first holes 1042 arranged along the first supply tube 1040 and the second supply tube 1050 includes a plurality of second holes 1052. arranged along the second supply tube 1050. The first supply tube 1040 may be positioned orthogonal to the second supply tube 1050 along a reference plane of the plenum volume 1030. Thus, the first supply tube 1040 may extend along an x-axis direction and the second supply tube 1050 may extend along a y-axis direction of the multi-zone showerhead pedestal 1000, or vice versa.

The first supply tube 1040 may be configured to deliver the first gas into the plenum volume 1030 and the second supply tube 1050 may be configured to deliver the second gas into the plenum volume 1030. In some implementations, the first gas is a precursor gas and the second gas is a dilution gas. In some implementations, the first gas is a dilution gas and the second gas is a precursor gas. In FIGS. 10A-10D, the first supply tube 1040 is shown oriented as a “vertical” tube and the second supply tube 1050 is shown oriented as a “horizontal” tube. However, it will be understood that the first supply tube 1040 may be interchanged with the second supply tube 1050 so that the first supply tube 1040 is “horizontal” and the second supply tube is “vertical.”

The multi-zone showerhead pedestal 1000 includes a plurality of baffles 1024 in the plenum volume 1030 for isolating the first gas from mixing with the second gas in the plenum volume 1030. That way, the first gas does not mix with the second gas until exiting the multi-zone showerhead pedestal 1000 through the plurality of gas distribution holes 1022 in the faceplate 1020. This delays mixing of the first gas with the second gas and facilitates greater control in obtaining a more parabolic or polynomial thickness profile during deposition. The mixing of the first gas and the second gas occur as the gases flow towards the semiconductor substrate. The plurality of baffles 1024 may separate the plenum volume 1030 into at least a first zone z1 and a second zone z2. The plurality of baffles 1024 may be parallel to one another. In some implementations, the plurality of baffles 1024 are parallel to the first supply tube 1040 and orthogonal to the second supply tube 1050. in some implementations, the second supply tube 1050 intersects through a center of each of the plurality of baffles 1024. A height of each of the plurality of baffles 1024 spans a gap distance between the backplate 1010 and the faceplate 1020.

As shown in FIGS. 10C and 10D, the plurality of baffles 1024 may include a plurality of first baffles 1024a and a plurality of second baffles 1024b. The plurality of first baffles 1024a include at least two baffles that are positioned on opposite sides of the first supply tube 1040 and closer to the first supply tube 1040 than the plurality of second baffles 1024b. The plurality of first baffles 1024a isolate or separate the first gas in the first zone z1 from the second gas in the second zone z2. In other words, the plurality of first baffles 1024a contain the first gas supplied from the first supply tube 1040 in the first zone z1 before exiting through some of the gas distribution holes 1022 of the faceplate 1020, and prevents the first gas from mixing with the second gas in the plenum volume 1030. The plurality of second baffles 1024b include at least two baffles that are positioned on opposite sides of the first supply tube 1040 and further from the first supply tube 1040 than the plurality of first baffles 1024a. The plurality of second baffles 1024b serve to further sub-divide the second zone z2 into multiple sections s1, s2, and s3. This sub-division into multiple sections s1, s2, and s3 prevents mixing of the second gas with each other from the sections s1, s2, and s3, thereby providing greater control of an amount of mass flow of the second gas from each section s1, s2, and s3. This allows modulation of the flow of second gas in the second zone z2, and enables greater control in obtaining a parabolic or polynomial thickness profile during deposition. In some implementations, the plurality of second baffles 1021b are not necessarily equally spaced apart, but may be positioned at predetermined locations for modulation of the flow of the second gas in the second zone z2.

The plurality of second baffles 1024b may sub-divide the second supply tube 1050 into any suitable number of sections such as sections s1, s2, and s3. The plurality of second holes 1052 in the second supply tube 1050 may be described by their geometries, diameters, spacing, arrangement, or number. These attributes of the plurality of second holes 1052 in the second supply tube 1050 may be variable among the sections s1, s2, and s3, or variable within each of the sections s1, s2, and s3. For example, the size/diameter of each of plurality of second holes 1052 may be variable in section s3 of the second zone z2, which may be useful to balance an effect of exhaust ports. In some implementations, the size/diameter of each of the plurality of second holes 1052 may be uniform in each section s1, s2, and s3, but variable among the multiple sections s1, s2, and s3. For instance, second holes 1052 in section s1 may be a certain size/diameter, and second holes 1052 in section s2 may be a different size/diameter than section s1, and second holes 1052 in section s3 may be a different size/diameter than either section s1 or section s2. Different-sized diameters or other attributes of the plurality of second holes 1052 may provide mass flow choking. This means that a maximum amount of flow of the second gas may be provided for each of the sections s1, s2, and s3 of the second supply tube 1050. The second holes 1052 in any of the sections s1, s2, and s3 may be designed in a manner so that it can handle a range of flow, and beyond a certain threshold the mass flow is choked. Below the threshold, an amount of flow may be controlled by simply varying flow rates of the second gas. Thus, the size/diameter of each of the plurality of second holes 1052 in the second supply tube 1050 may be non-uniform. In some implementations, the size/diameter of each of the plurality of first holes 1042 in the first supply tube 1040 may be uniform. Though the foregoing description is applied to sub-dividing a second supply tube 1050 into multiple sections and having varying attributes (e.g., geometry, diameter, number, spacing, or arrangement) of the second holes 1052 among the sections, it will be understood by a person skilled in the art that the first supply tube 1040 may alternatively be sub-divided into multiple sections and have varying attributes (e.g., geometry, diameter, number, spacing, or arrangement) of the first holes 1042 among the sections.

FIG. 11 shows a graph illustrating inert gas flow from a showerhead pedestal in different sections of a zone according to some implementations. The inert gas may be flowed from a supply tube such as a second supply tube described in FIGS. 10A-10D. The second supply tube may be divided into a first zone z1, a first section s1 of a second zone z2, a second section s2 of the second zone z2, and a third section s3 of the second zone z2. There is no inert as flow in the first zone z1 because placement of baffles in a plenum volume of the showerhead pedestal prevents the inert gas from being flowed in the first zone if. In the first section s1 of the second zone z2, mass flow of the inert gas gradually increases along the length of the second supply tube to a maximum mass flow of about 2×10⁻⁶ kg/s, In the second section s2 of the second zone z2, mass flow of the inert gas gradually increases along the length of the second supply tube to a mass flow of about 2.5×10⁻⁶ kg/s, and gradually increases further along the length of the second supply tube to a maximum mass flow of about 7.5×10⁻⁵ kg/s. In the third section s3 of the second zone z2, mass flow of the inert gas remains constant at about 7.5×10⁻⁶ kg/s. This shows that mass flow of a second gas out of a showerhead pedestal is tunable across multiple sections s1, s2, and s3 along a second supply tube. Mass flow choking along the length of a supply tube may serve to tightly control dilution of a precursor gas, thereby providing increased control in obtaining a parabolic or polynomial thickness profile during deposition. This facilitates greater tunability of stress based on a level of asymmetry in bowing along the x-axis and y-axis direction of a bowed semiconductor substrate.

In some implementations, a ratio of precursor gas flow rate to inert gas flow rate may be controlled for modulating a concentration of precursor gas adjacent to a semiconductor substrate. Where the ratio is higher, more precursor gas is flowed along an axial length of the showerhead pedestal such as an x-axis or y-axis direction of the showerhead pedestal. As a result, the concentration of precursor gas tapers less (i.e., shallow slope) along the axial length. Where the ratio is lower, less precursor gas is flowed along the axial length of the showerhead pedestal. As a result, the concentration of precursor gas tapers more (i.e., steep slope) along the axial length. The ratio of the precursor gas flow rate to the inert gas flow rate may be controlled to optimize curve-fitting for a precursor mass flow profile. The precursor mass flow profile may correlate directly to a film thickness profile. The ratio of the precursor gas flow rate to the inert gas flow rate may be tuned to obtain a more parabolic or polynomial film thickness profile. In fact, by controlling the ratio, non-parabolic profiles such as flat, bell curve, log profiles, and other profiles are also achievable. A wide range of mass flow profiles or film thickness profiles may be achieved from the showerhead pedestal by controlling the ratio of precursor gas flow rate to inert gas flow rate.

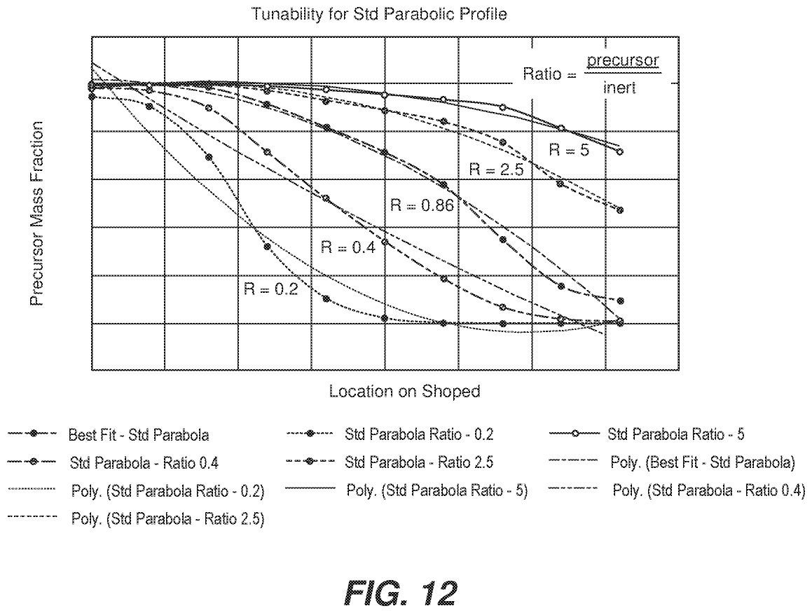

FIG. 12 shows a graph illustrating precursor mass flow profile from a showerhead pedestal for various ratios of precursor gas to inert gas according to some implementations. Precursor mass fraction is measured as a function of location on a showerhead pedestal. As shown in FIG. 12, varying a ratio of precursor flow to inert gas flow allows tunability of precursor mass flow profiles. Depending on the ratio, the precursor mass flow profile may closely fit a standard parabolic or polynomial function. At a ratio of 5:1, the precursor mass flow profile moderately fits a standard parabolic profile. At a ratio of 2.5:1, the precursor mass flow profile closely fits a standard parabolic profile. At a ratio of 0.86:1, the precursor mass flow profile closely fits a standard parabolic profile. At a ratio of 0.4:1, the precursor mass flow profile does not closely fit a standard parabolic profile. At a ratio of 0,2:1, the precursor mass flow profile does not closely fit a standard parabolic profile.

Disclosed embodiments may be performed in any suitable apparatus or tool. An apparatus or tool may include one or more process stations. Described below are example process stations and tools that may be used in some embodiments.

FIG. 13 illustrates a schematic diagram of an example process tool for performing operations for stress modulation according to some implementations. The multi-station processing tool 1300 can include an inbound load lock 1302 and an outbound load lock 1304, either or both of which may comprise a plasma source and/or UV source. A robot 1306, at atmospheric pressure, is configured to move wafers from a cassette loaded through a pod 1308 into inbound load lock 1302 via an atmospheric port 1310. A wafer (not shown) is placed by the robot 1306 on a pedestal 1312 in the inbound load lock 1302, the atmospheric port 1310 is closed, and the load lock inbound 1302 is pumped down. Where the inbound load lock 1302 includes a remote plasma source, the wafer may be exposed to a remote plasma treatment in the inbound load lock 1302 prior to being introduced into a processing chamber 1314. Further, the wafer also may be heated in the inbound load lock 1302 as well, for example, to remove moisture and adsorbed gases. Next, a chamber transport port 1316 to processing chamber 1314 is opened, and another robot (not shown) places the wafer into the reactor on a pedestal of a first station shown in the reactor for processing. While the implementation depicted in FIG. 13 includes load locks, it will be appreciated that, in some implementations, direct entry of a wafer into a process station may be provided.

The depicted processing chamber 1314 includes four process stations, numbered from 1 to 4 in the embodiment shown in FIG. 13, Each station has a heated pedestal (shown at 1318 for station 1), and gas line inlets. It will be appreciated that in some embodiments, each process station may have different or multiple purposes. For example, in some embodiments, a process station may be switchable between a CVD and PECVD process mode. In another example, deposition operations such as PECVD operations may be performed in one station, while exposure to UV radiation for UV curing may be performed in another station. In some embodiments, deposition and UV curing are performed in the same station. While the depicted processing chamber 1314 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 13 depicts an implementation of a wafer handling system 1390 for transferring wafers within processing chamber 1314. In some embodiments, wafer handling system 1390 may transfer wafers between various process stations and/or between a process station and a load lock. It will be appreciated that any suitable wafer handling system may be employed. Non-limiting examples include wafer carousels and wafer handling robots. FIG. 13 also depicts an implementation of a system controller 1350 employed to control process conditions and hardware states of process tool 1300. System controller 1350 may include one or more memory devices 1356, one or more mass storage devices 1354, and one or more processors 1352. Processor 1352 may include a CPU or computer, analog, and/or digital input/output connections, stepper motor controller boards, etc.

In some embodiments, system controller 1350 controls all of the activities of process tool 1300. System controller 1350 executes system control software 1358 stored in mass storage device 1354, loaded into memory device 1356, and executed on processor 1352. Alternatively, the control logic may be hard coded in the controller 1350. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 1358 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 1300, System control software 1358 may be configured in any suitable way. For example, various process tool component subroutines or control objects may be written to control operation of the process tool components used to carry out various process tool processes. System control software 1358 may be coded in any suitable computer readable programming language.

In some embodiments, system control software 1358 may include input/output control (IOC) sequencing instructions for controlling the various parameters described above. Other computer software and/or programs stored on mass storage device 1354 and/or memory device 1356 associated with system controller 1350 may be employed in sonic embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 1318 and to control the spacing between the substrate and other parts of process tool 1300.

A process gas control program may include code for controlling gas composition (e.g., silicon-containing gases, oxygen-containing gases, nitrogen-containing gases, and dilution or inert gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 1350. The user interface may include a display screen, graphical software displays of the apparatus and/or process conditions, and user input devices such as pointing devices, keyboards, touch screens, microphones, etc.

In some embodiments, parameters adjusted by system controller 1350 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 1350 from various process tool sensors. The signals for controlling the process may be output on the analog and digital output connections of process tool 1300. Non-limiting examples of process tool sensors that may be monitored include mass flow controllers, pressure sensors such as manometers), thermocouples, etc. Appropriately programmed feedback and control algorithms may be used with data from these sensors to maintain process conditions.

System controller 1350 may provide program instructions for implementing the above-described deposition processes. The program instructions may control a variety of process parameters, such as DC power level, RF bias power level, pressure, temperature, etc. The instructions may control the parameters to operate deposition of film stacks of a bow compensation layer according to various embodiments described herein.

The system controller 1350 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 1350.

In some implementations, the system controller 1350 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 1350, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 1350 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 1350 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 1350, in some implementations, may be a part of or coupled to a computer that is integrated with, coupled to the system, otherwise networked to the system, or a combination thereof. For example, the system controller 1350 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 1350 receives instructions in the form of data, which specify parameters for each of the processing steps to be performed during one or more operations. It should be understood that the parameters may be specific to the type of process to be performed and the type of tool that the system controller 1350 is configured to interface with or control. Thus as described above, the system controller 1350 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

### Other Embodiments

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
providing a bowed semiconductor substrate having one or more tensile regions and one or more compressive regions;
depositing a compressive film having a first non-linear thickness profile on a backside of the bowed semiconductor substrate; and
depositing, prior to or after depositing the compressive film, a tensile film having a second non-linear thickness profile on the backside of the bowed semiconductor substrate, wherein the compressive film and the tensile film together form a bow compensation layer.

2. The method of claim 1, wherein the first non-linear thickness profile is a first parabolic-shaped profile and the second non-linear thickness profile is a second parabolic-shaped profile.

3. The method of claim 2, wherein the first parabolic-shaped profile opens upwards or downwards, and the second parabolic-shaped profile opens in a direction opposite the first parabolic-shaped profile.

4. The method of claim 1, wherein the bow compensation layer is flat or substantially flat.

5. The method of claim 1, wherein each of the first and second non-linear thickness profiles matches or substantially matches a polynomial function.

6. The method of claim 1, wherein the bowed semiconductor substrate is saddle-shaped prior to depositing the bow compensation layer.

7. The method of claim 1, wherein the bowed semiconductor substrate is asymmetrically bowed having a warpage equal to or greater than +300 μm or equal to or less than −300 μm, and wherein the bowed semiconductor substrate after deposition of the bow compensation layer is between −300 μm and +300 μm.

8. The method of claim 1, wherein depositing the compressive film comprises controlling a first precursor concentration from a showerhead pedestal to vary across the backside of the bowed semiconductor substrate, and wherein depositing the tensile film comprises controlling a second precursor concentration from the showerhead pedestal to vary across the backside of the bowed semiconductor substrate.

9. The method of claim 8, wherein the showerhead pedestal comprises a first supply tube and a second supply tube in a plenum volume of the showerhead pedestal, wherein the first supply tube flows a first gas to a first zone of the plenum volume and the second supply tube flows a second gas to a second zone of the plenum volume during deposition of the compressive film or the tensile film.

10. A showerhead comprising:
a faceplate that comprises a plurality of gas distribution holes through which gas is flowed out of the showerhead;
a backplate opposite the faceplate and defining a plenum volume therebetween;
a first supply tube in the plenum volume, the first supply tube having a plurality of first holes that supplies a first gas into the plenum volume;
a second supply tube in the plenum volume, the second supply tube having a plurality of second holes that supplies a second gas into the plenum volume; and
a plurality of baffles in the plenum volume, wherein the plurality of baffles are configured to at least isolate the first gas from the second gas in the plenum volume.

11. The showerhead of claim 10, wherein the first supply tube is orthogonal to the second supply tube along a reference plane of the plenum volume.

12. The showerhead of claim 10, wherein the plurality of baffles comprise a plurality of first baffles and a plurality of second baffles, wherein the plurality of first baffles are parallel to the first supply tube and on opposite sides of the first supply tube to isolate the first gas in a first zone from a second zone of the plenum volume, and wherein the plurality of second baffles comprise at least two baffles parallel to the first supply tube and on opposite sides of the first supply tube further from the plurality of first baffles, wherein the plurality of second baffles are configured to divide a flow of the second gas in the second zone into a plurality of sections.

13. The showerhead of claim 12, wherein the first gas flows out of the faceplate from the first zone of the plenum volume and the second gas flows out of the faceplate from the second zone of the plenum volume, wherein the faceplate is configured to face a backside of a semiconductor substrate.

14. The showerhead of claim 12, wherein a diameter of each of the plurality of first holes across the first supply tube is uniform, and wherein a diameter of the second holes in each of the plurality of sections in the second zone is non-uniform.

15. The showerhead of claim 10, wherein a height of each of the plurality of baffles spans a gap distance between the backplate and the faceplate.

16. The showerhead of claim 10, further comprising:
a center plug in the plenum volume and in fluid communication with each of the first supply tube and the second supply tube, wherein the center plug directs a flow of the first gas to the first supply tube and a flow of the second gas to the second supply tube.

17. The showerhead of claim 10, wherein the first gas is a precursor gas and the second gas is a dilution gas.

18. The showerhead of claim 10, further comprising:
a stem connected to the backplate and in fluid communication with the plenum volume, wherein the stem comprises one or more gas delivery lines that supplies the first gas and the second gas to the first supply tube and the second supply tube.

19. A showerhead comprising:
a faceplate that comprises a plurality of gas distribution holes through which gas is flowed out of the showerhead;
a backplate opposite the faceplate and defining a plenum volume therebetween;
one or more baffles in the plenum volume that divides the plenum volume into at least a first zone and a second zone; and
one or more gas inlets coupled to the backplate that delivers a first gas and a second gas into the plenum volume, wherein the first gas is configured to be delivered to the first zone and the second gas is configured to be delivered to the second zone.

20. The showerhead of claim 19, wherein the plurality of gas distribution holes comprises first holes in fluid communication with the first zone and second holes in fluid communication with the second zone, wherein a density of the first holes is different than a density of the second holes.
